(19) United States
(12) Patent Application Publication
(10) Pub. No.: US 2014/0340237 A1
(43) Pub. Date: Nov. 20, 2014

(54) APPLIANCE MANAGEMENT SYSTEM AND APPLIANCE MANAGEMENT METHOD

(71) Applicant: PANASONIC CORPORATION, Kadoma-shi, Osaka (JP)

(72) Inventors: Kenji Kuniyoshi, Osaka (JP); Junichi Suzuki, Osaka (JP); Yasuhiro Yanagi, Osaka (JP); Hideki Takenaga, Osaka (JP)

(21) Appl. No.: 14/375,685

(22) PCT Filed: Feb. 8, 2013
(86) PCT No.: PCT/JP2013/000690

§ 371 Date: Jul. 30, 2014

(30) Foreign Application Priority Data
Feb. 21, 2012 (JP) 2012-035289

(51) Int. Cl. G01D 4/00; G01R 21/00; H04Q 9/00; G01R 11/00

(52) U.S. Cl. CPC G01D 4/00; G01R 11/00; G01R 21/00; H04Q 9/00
USPC 340/870.02

(57) ABSTRACT

The appliance management system according to the present invention includes: a meter device configured to measure a predetermined physical amount; an appliance having a predetermined function; and a management device. The management device sends first information including a first identifier allocated to the appliance and a second identifier allocated to the meter device. The meter device sends, when the second identifier included in the first information received from the management device matches the second identifier allocated to this meter device, second information including the first identifier included in the first information and the second identifier allocated to this meter device. The appliance performs, when the first identifier included in the second information received from the meter device matches the first identifier allocated to this appliance, a setting process of selecting the meter device identified by the second identifier included in the second information as a communication partner.

### TECHNICAL FIELD

The present invention relates to appliance management systems and appliance management methods, and particularly to an appliance management system in which a meter device and an appliance that are installed in a facility, communicate with each other, and an appliance management method.

### BACKGROUND ART

In the past, there has been proposed a meter device (energy meter) installed in a facility (home) that sends a result of meter reading (energy consumption of a commercial power source) to an electric power company through communication such as power line communication or wireless communication to enable remote meter reading (e.g., see document 1 [JP 2011-78169 A (paragraphs [0035], [0051], and [0074])]). The meter device disclosed in patent document 1 is configured to not only communicate with an electric power company but also communicate with an appliance (power conditioner) installed in a facility in a power line communication manner or a wireless communication manner.

Thus, the appliance capable of communicating with the meter device can easily obtain electric energy information measured by the meter device, and therefore accurate energy management can be realized. Additionally, this appliance (power conditioner) is configured to communicate with a display device in a home, and transmits energy-related information including the electric energy information to the display device to display the energy-related information in a visible manner for a user.

As described above, to enable communication between the meter device and the appliance installed in the facility, the appliance is required to establish connection with the meter device. In other words, in the case of addition or replacement of appliances, to start communication between a new appliance and the meter device, settings for establishing connection between the meter device and the appliance is necessary.

However, the meter device is normally under the control of the electric power company, and thus a user does not have an interface for inputting data to the meter device. Hence, it is demanded that connection can be established without manually inputting data for identifying the appliance to the meter device. If the device to communicate with the meter device is only a power conditioner, for example, a worker can perform settings for establishing connection between the appliance and the meter device when the worker installs the appliance. However, in view of the fact that the appliance to communicate with the meter device may be added or replaced, it is not efficient that the worker performs the settings every time.

### SUMMARY OF INVENTION

In view of the above insufficiency, the present invention has aimed to propose an appliance management system and an appliance management method that are capable of facilitating settings for establishing connection between an appliance and a meter device.

The appliance management system of the first aspect in accordance with the present invention includes: a meter device configured to measure a predetermined physical amount; an appliance having a predetermined function; and a management device. The management device is configured to, when obtaining a first identifier allocated to the appliance and a second identifier allocated to the meter device, send first information including the first identifier and the second identifier. The meter device is configured to: when receiving the first information, judge whether the second identifier included in the first information matches the second identifier allocated to this meter device; and when the second identifier included in the first information matches the second identifier allocated to this meter device, send second information including the first identifier included in the first information and the second identifier allocated to this meter device. The appliance is configured to: when receiving the second information, judge whether the first identifier included in the second information matches the first identifier allocated to this appliance; and when the first identifier included in the second information matches the first identifier allocated to this appliance, perform a setting process of selecting the meter device identified by the second identifier included in the second information as a communication partner.

In the appliance management system of the second aspect in accordance with the present invention referring to the first aspect, the appliance and the meter device each have a function of communicating in a connection oriented protocol. The appliance is configured to, after completion of the setting process, perform a connection process of sending a connection request for establishing connection with the communication partner in the connection oriented protocol. The meter device is configured to, when receiving the connection request, send a connection reply to a sender of the connection request. The appliance is configured to, when receiving the connection reply after completion of the connection process, determine that connection with the communication partner is established.

In the appliance management system of the third aspect in accordance with the present invention referring to the second aspect, the appliance and the meter device each have a function of communicating in a connectionless protocol. The meter device is configured to send the second information in the connectionless protocol.

In the appliance management system of the fourth aspect in accordance with the present invention referring to the third aspect, the management device is configured to, when obtaining the first identifier and the second identifier, send the first information to the meter device identified by the second identifier obtained.

In the appliance management system of the fifth aspect in accordance with the present invention referring to the fourth aspect, the appliance management system further includes a communication terminal configured to communicate with the management device and the meter device. The management device is configured to, when connection between the appliance and the meter device respectively identified by the first identifier and the second identifier included in the first information has not yet been established even after a lapse of a predetermined time period from sending the first information, send the first information to the communication terminal. The communication terminal is configured to, when receiving the first information, send the first information to the meter device identified by the second identifier included in the first information.

In the appliance management system of the sixth aspect in accordance with the present invention referring to the fifth aspect, the meter device is configured to send a connection establishment signal to the management device after sending the connection response. The management device is configured to, when having not yet received the connection establishment signal even after a lapse of the predetermined time period from sending the first information, send the first information to the communication terminal.

In the appliance management system of the seventh aspect in accordance with the present invention referring to the third aspect, the appliance management system further comprises a communication terminal configured to communicate with the management device and the meter device. The management device is configured to, when obtaining the first identifier and the second identifier, send the first information to the communication terminal. The communication terminal is configured to, when receiving the first information, send the first information to the meter device identified by the second identifier included in the first information.

The appliance management system of the eighth aspect in accordance with the present invention includes: a meter device configured to measure a predetermined physical amount; an appliance having a predetermined function; and a management device. The management device is configured to, when obtaining a first identifier allocated to the appliance and a second identifier allocated to the meter device, produce a setting code for identifying the meter device associated with the second identifier based on the first identifier and the second identifier. The appliance is configured to, when receiving the setting code, perform a setting process of selecting the meter device identified by the setting code as a communication partner.

In the appliance management system of the ninth aspect in accordance with the present invention referring to the eighth aspect, the appliance and the meter device each have a function of communicating in a connection oriented protocol. The appliance is configured to, after completion of the setting process, perform a connection process of sending a connection request for establishing connection with the communication partner in the connection oriented protocol. The meter device is configured to, when receiving the connection request, send a connection reply to a sender of the connection request. The appliance is configured to, when receiving the connection reply after completion of the connection process, determine that connection with the communication partner is established.

The appliance management method of the tenth aspect in accordance with the present invention is an appliance management method for establishing connection between a meter device configured to measure a predetermined physical amount and an appliance having a function of communicating with the meter device. The appliance management method includes first to sixth steps. The first step is a step of, by a management device, obtaining a first identifier allocated to the appliance and a second identifier allocated to the meter device. The second step is a step of, by the management device, sending first information including the first identifier and the second identifier. The third step is a step of, by the meter device, receiving the first information and judging whether the second identifier included in the first information matches the second identifier allocated to this meter device. The fourth step is a step of, by the meter device, sending second information including the first identifier included in the first information and the second identifier allocated to this meter device when the second identifier included in the first information matches the second identifier allocated to this meter device. The fifth step is a step of, by the appliance, receiving the second information and judging whether the first identifier included in the second information matches the first identifier allocated to this appliance. The sixth step is a step of, by the appliance, selecting the meter device identified by the second identifier included in the second information as a communication partner when the first identifier matches the first identifier allocated to this appliance.

In the appliance management method of the eleventh aspect in accordance with the present invention referring to the tenth aspect, the appliance management method further includes seventh to ninth steps. The seventh step is a step of, by the appliance, sending a connection request for establishing connection with the communication partner in a connection oriented protocol, after the sixth step. The eighth step is a step of, by the meter device, receiving the connection request and sending a connection reply to a sender of the connection request. The ninth step is a step of, by the appliance, determining that connection with the communication partner is established when receiving the connection reply.

In the appliance management method of the twelfth aspect in accordance with the present invention referring to the eleventh aspect, in the fourth step, the meter device sends the second information in a connectionless protocol.

In the appliance management method of the thirteenth aspect in accordance with the present invention referring to the twelfth aspect, in the second step, the management device sends the first information to the meter device identified by the second identifier obtained.

In the appliance management method of the fourteenth aspect in accordance with the present invention referring to the thirteenth aspect, the appliance management method further includes a tenth step and an eleventh step. In the tenth step, when connection between the appliance and the meter device respectively identified by the first identifier and the second identifier included in the first information has not yet been established even after a lapse of a predetermined time period from sending the first information, the management device sends the first information to a communication terminal configured to communicate with the management device and the meter device. In the eleventh step, when receiving the first information, the communication terminal sends the first information to the meter device identified by the second identifier included in the first information.

In the appliance management method of the fifteenth aspect in accordance with the present invention referring to the fourteenth aspect, the appliance management method further includes a twelfth step and a thirteenth step. In the twelfth step, the meter device sends a connection establishment signal to the management device after sending the first information. In the thirteenth step, when having not yet received the connection establishment signal even after a lapse of the predetermined time period from sending the first information, the management device sends the first information to the communication terminal.

### BRIEF DESCRIPTION OF THE DRAWINGS

FIG. 1 is a system configuration diagram illustrating the appliance management system in accordance with the first embodiment.

FIG. 2 is a system configuration diagram illustrating an operation of the appliance management system in accordance with the first embodiment.

FIG. 3 is a system configuration diagram illustrating an operation of the appliance management system in accordance with the second embodiment.

### DESCRIPTION OF EMBODIMENTS

### First Embodiment

### 1. Configuration of Appliance Management System 10

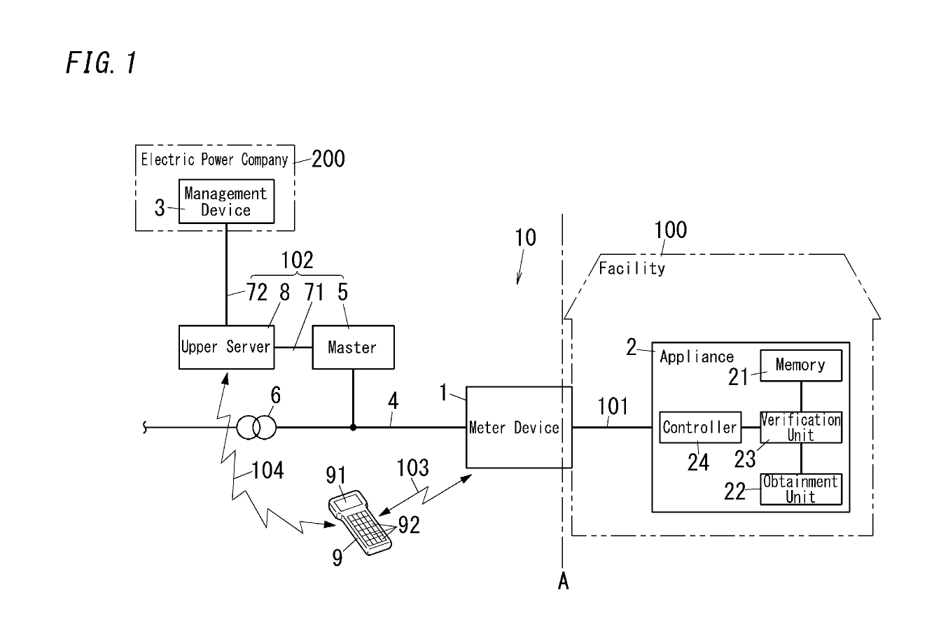

As shown in FIG. 1, the appliance management system 10 of the present embodiment includes a meter device 1, an appliance 2, and a management device 3. The meter device 1 and the appliance 2 are installed in a facility 100, and the management device 3 is operated by an electric power company (electric power supplier) 200. In the following example, the facility 100 is one of dwelling units in a condominium. However, the facility 100 is not limited to such a dwelling unit, but may be a residence, an office, or a factory.

In other words, the appliance management system 10 of the present embodiment includes a plurality of meter devices 1, a plurality of appliances 2, and the management device 3. The management device 3 is used for establishing connection between a particular appliance 2 of the plurality of appliances 2 and a particular meter device 1 of the plurality of meter devices 1. The particular meter device 1 is a meter device 1 which is situated in the same region (in the present embodiment, the facility 100) in which the particular appliance 2 is situated.

The meter device 1 is configured to measure a predetermined physical amount. In the present embodiment, the meter device 1 is an energy meter configured to measure electric energy. For example, the meter device 1 is connected to a distribution line 4 for transmitting commercial energy from the electric power company 200, and is to measure electric energy being supplied to the facility 100. In short, the meter device 1 is configured to measure electric energy being supplied through a predetermined power transmission line (in the present embodiment, the distribution line 4).

The meter device 1 is a so-called smart meter. To enable remote meter-reading, the meter device 1 is designed to communicate with a master 5 connected to the distribution line 4 to send a measurement result (meter-reading data) to the electric power company 200. Communication between the master 5 and the meter device 1 is realized by wireless communication, power line communications (PLC), or the like.

As describe below, the meter device 1 has a function of communicating with the appliance 2 in the facility 100. Note that, commercial energy is to be supplied from an electric power substation to a pole transformer 6 that is attached to a utility pole situated in a vicinity of the facility 100. The pole transformer 6 lowers a voltage of the commercial energy and supplies the resultant commercial energy to the facility 100. Note that, the meter device 1 may be configured to measure a physical amount different from the electric energy.

The master 5 is attached to a utility pole in a vicinity of the facility 100, for example. The master 5 is configured to send information such as the measurement result of the meter device 1 to the upper server 8 through a dedicated line 71 constituted by optic fibers, for example.

There are a plurality of upper servers 8 provided in individual regions, and each upper server 8 is configured to communicate with the management device 3 installed in the electric power company 200 through a corresponding dedicated line 72.

Accordingly, there is a second communication path 102 formed between the management device 3 of the electric power company 200 and the meter device 1. The second communication path 102 includes the upper server 8, the dedicated lines 71 and 72, and the master 5. The second communication path 102 is included in an information transmission route (so-called “A-route”) between the meter device 1 and the electric power company 200.

Additionally, the appliance management system 10 of the present embodiment further includes a communication terminal (maintenance terminal) 9 to be carried by a worker of the electric power company 200.

The maintenance terminal 9 includes a display unit 91 and a manual interface unit 92. The maintenance terminal 9 has a function of performing near-field communication with the meter device 1 through a third communication path 103 and a function of communicating with the management device 3 through a fourth communication path 104. In short, the appliance management system 10 of the present embodiment further includes the communication terminal (maintenance terminal) 9 configured to communicate with the management device 3 and the meter device 1.

The third communication path 103 and the fourth communication path 104 are each constructed by using wireless communication technologies. The fourth communication path 104 is included in the information transmission route (so-called “A-route”) between the meter device 1 and the electric power company 200.

Note that, the maintenance terminal 9 is used for the purpose of maintenance and inspection of the meter device 1, by the worker of the electric power company at the site (facility 100), for example. Hence, near field communication for a short distance of several meters is used for communication between the maintenance terminal 9 and the meter device 1. Consequently, in a case where the maintenance terminal 9 tries to communicate with the meter 1 of a desired facility 100, the maintenance terminal 9 does not accidentally communicate with a meter device 1 of a neighboring facility, for example.

Note that, in the present embodiment, the fourth communication path 104 is formed between the upper server 8 and the maintenance terminal 9, and the maintenance terminal 9 communicates with the management device 3 through the dedicated line 72 and the upper server 8. The communication between the maintenance terminal 9 and the upper server 8 is not limited to near field communication, but may be long distance communication or wired communication using dedicated cables.

The appliance 2 has a predetermined function. For example, the appliance 2 is an electric appliance configured to communicate with the meter device 1 through a first communication path 101 to operate in cooperation with the meter device 1. In summary, the appliance 2 is a cooperation appliance.

Such an appliance 2 has a function of directly communicating with the meter device 1. And, the appliance 2 does not have a function of communicating appliances other than the meter device 1. In short, the appliance 2 is not configured to directly communicate with the management device 3.

Examples of the appliance 2 may include an energy monitoring appliance allowing a television, a home information board, or the like to display information such as the measurement result of the meter device 1, and a HEMS (Home Energy Management System) appliance connected to various types of loads in the facility 100.

The HEMS appliance may send information such as power consumptions of loads to the electric power company 200 by way of the meter device 1, and may control loads based on signals sent from the electric power company 200 to suppress peaks of energy demand (i.e., peak cut).

The first communication path 101 may be formed by use of technologies such as wireless communication and power line communication. The first communication path 101 is included in an information transmission route (so-called “B-route”) that enables direct obtainment of information from the meter device 1.

The appliance 2 includes: a memory 21 storing registration data described below; an obtainment unit 22 configured to obtain the registration data from the meter device 1; a verification unit 23 configured to verify the registration data; and a controller 24 configured to establish connection between the appliance 2 and the meter device 1. Detailed operations of the memory 21, the obtainment unit 22, the verification unit 23, and the controller 24 are described later.

The border “A” of the responsibility between the electric power company 200 and residents of the facility 100 is at the meter device 1. Accordingly, the residents of the facility 100 is responsible for managing the first communication path 101 and the appliance 2, and the electric power company is responsible for managing the management device 3, the meter device 1, the second to fourth communication paths 102 to 104, and the maintenance terminal 9.

In the appliance management system 10 having the aforementioned configuration, at the time of system installation, or adding or replacing the appliance 2, to enable starting communication between a new appliance 2 and the meter device 1, settings for establishing the connection between the meter device 1 and the appliance 2 is necessary.

Note that, the meter device 1 is normally managed by the electric power company 200, and a user (resident of the facility 100) does not have an interface for manually inputting data into the meter device 1. Hence, it is desired that the connection between the meter device 1 and the appliance 2 can be established without manually inputting data for identifying the appliance 2.

In view of this, the appliance management system 10 of the present embodiment performs connection between the meter device 1 and the appliance 2 by use of Note, that the term “connection” in the present embodiment means not physical connection but that bidirectional communication is enabled.

In a first scheme, the appliance management system 10 makes the connection between the meter device 1 and the appliance 2 by use of the second communication path 102.

For example, when receiving the registration data allocated to the appliance 2 and identification data for identifying the meter device 1 installed in the same facility 100 in which the appliance 2 is installed, the management device 3 sends the registration data to the meter device 1 identified by the identification data.

The registration data is a unique number (registration number) preliminarily allocated to the appliance 2, for example. The registration data is preliminarily stored in the memory 21 of the appliance 2, and the content indicated by the registration data is shown on a nameplate (not shown) of the appliance 2.

The identification data may be a unique number (meter number) preliminarily allocated to the meter device 1, or information uniquely associated with the meter device 1 such as an address of the facility 100, a phone number, an ID of a party to a contract, for example.

The registration data and the identification data may be inputted into the management device 3 by a user who accesses a website of the electric power company 200 through the Internet by use of an information terminal (not shown) such as a personal computer. Alternatively, the registration data and the identification data may be sent from the appliance management system 10 to the electric power company by mail, and is inputted into the management device 3 by a person in charge at the electric power company 200.

In this embodiment, when information such as the address of the facility 100 is inputted as the identification data, the management device 3 searches a database for the meter number associated with the address, and subsequently uses this meter number as the identification data. The meter number is preliminarily stored in a memory of the meter device 1, and is shown on a nameplate (not shown) of the meter device 1. Accordingly, the management device 3 may be configured to, when receiving the identification data, obtain the meter number based on the identification data.

As described above, the management device 3 is configured to, when obtaining a first identifier (registration number) allocated to the appliance 2 and a second identifier (meter number) allocated to the meter device 1, send first information including the first identifier (registration number) and the second identifier (meter number).

According to the first scheme, the management device 3 is configured to, when obtaining the first identifier (registration number) and the second identifier (meter number), send the first information to the meter device 1 identified by the second identifier (meter number) obtained. For example, the first information is a communication signal including the second identifier as a destination and the first identifier as data.

In the present embodiment, the management device 3 sends the registration data together with the identification data to the upper server 8 connected to the meter device 1 identified by the inputted identification data.

In this regard, the management device 3 may confirm that the input of the identification data is done by a qualified user, by verifying the address based on the inputted ID of a party to a contract with using a database, and send the registration data. In contrast, when the address is not associated with the ID of a party to a contract, the management device 3 determines that the input is done by an unqualified user, and does not send the registration data. Additionally, the management device 3 may confirm that the inputted registration data is a qualified registration data, by use of an external database for managing information such as the registration numbers of the appliances 2, and send the registration data.

The upper server 8 transfers the registration data to the meter device 1 identified by the identification data received from the management device 3 by way of the dedicated line 71 and the master 5. In summary, the management device 3 sends the registration data to the meter device 1 identified by the inputted identification data through the second communication path 102.

In this regard, the management device 3 determines a destination of the registration data by use of the identification data (meter number) unique to the meter device 1, and hence the meter device 1 can receive only the registration data destined to this meter device 1. When receiving the registration data from the management device 3, the meter device 1 sends this registration data through the first communication path 101 to the appliance 2 in the same facility in which the meter device 1 is installed.

Accordingly, the meter device 1 is configured to, when receiving the first information, judge whether the second identifier (meter number) included in the first information matches the second identifier (meter number) allocated to this meter device 1. The meter device 1 is configured to, when the second identifier (meter number) included in the first information matches the second identifier (meter number) allocated to this meter device 1, send second information including the first identifier (registration number) included in the first information and the second identifier (meter number) allocated to this meter device 1. For example, the second information is a communication signal including the first identifier as a destination and the second identifier as data.

The meter device 1 and the appliance 2 each have a function of communicating in a connection oriented protocol, and a function of communicating in a connectionless protocol.

The meter device 1 is configured to send the second information to the appliance 2 in the connectionless protocol. In other words, the meter device 1 is configured to send the second information to the appliance 2 without establishing the connection with the appliance 2.

Furthermore, the meter device 1 is configured to communicate with the appliance 2 in the connection oriented protocol in response to a request from the appliance 2. The meter device 1 is configured to, when receiving a connection request from the appliance 2, send a connection reply to a sender of the connection request.

The appliance 2 obtains the registration data at the obtainment unit 22 by receiving the registration data through the first communication path 101 from the meter device 1.

When receiving the registration data from the meter device 1, the appliance 2 checks, by the verification unit 23, whether the registration data (hereinafter referred to as “first data”) obtained by the obtainment unit 22 matches the registration data (hereinafter referred to as “second data”) stored in the memory 21.

When the first data matches the second data, the appliance 2 establishes by the controller 24 the connection with the meter device 1 being the sender of the registration data, and starts to communicate with this meter device 1.

Accordingly, the appliance 2 is configured to, when receiving the second information, judge whether the first identifier (first data) included in the second information matches the first identifier (second data) allocated to this appliance 2. The appliance 2 is configured to, when the first identifier included in the second information matches the first identifier allocated to this appliance 2, perform a setting process of selecting the meter device 1 identified by the second identifier included in the second information as a communication partner.

Further, the appliance 2 is configured to, after completion of the setting process, perform a connection process of sending the connection request for establishing connection with the communication partner in the connection oriented protocol. The appliance 2 is configured to, when receiving the connection reply after completion of the connection process, determine that connection with the communication partner is established. Note that, after completion of the setting process, the appliance 2 can perform the connection process at any timing. In the present embodiment, the appliance 2 performs the connection process subsequent to the setting process. In brief, the appliance 2 checks whether the communication between the appliance 2 and the meter device 1 can be established actually.

As described above, the appliance 2 establishes the connection with the meter device 1 in the connection oriented protocol by performing the connection process. After establishing the connection with the meter device 1, the appliance 2 communicates with the meter device 1 at a desired timing. For example, the appliance 2 sends a request for energy information to the meter device 1 at a desired timing. The meter device 1 sends energy information to the appliance 2 in response to reception of the request for energy information.

In summary, according to the aforementioned first scheme, when the newly added appliance 2 receives the registration data allocated to this appliance 2 from the meter device 1, this appliance 2 accepts the sender of this registration data as the communication partner, and establishes the connection with this meter device 1. In other words, after completion of the connection with the meter device 1 in the same facility, the appliance 2 can operate in cooperation with this meter device 1 by communicating with this meter device 1.

Additionally, the meter device 1 judges whether establishment of the connection with the appliance 2 has succeeded, at a time at which a predetermined time has elapsed from sending the registration data to the appliance 2, and sends a result of this judgment to the management device 3 through the second communication path 102. For example, when the meter device 1 receives a reply from the appliance 2 within the predetermined time period, the meter device 1 determines that the establishment of the connection with the appliance 2 has succeeded. When the meter device 1 does not receive the reply within the predetermined time period, the meter device 1 determines that the establishment of the connection has been failed.

Accordingly, for example, if the establishment of the connection between the meter device 1 and the appliance 2 results in failure due to communication errors between the meter device 1 and the appliance 2, the management device 3 can retry to establish the connection between the meter device 1 and the appliance 2 by resending the registration data to the meter device 1.

For example, when the meter device 1 has not yet received the connection reply even after a lapse of the predetermined time period from sending the second information, the meter device 1 determines that the establishment of the connection between the meter device 1 and the appliance 2 has failed. When the meter device 1 determines that the establishment of the connection between the meter device 1 and the appliance 2 has failed, the meter device 1 requests the management device 3 to resend the first information. Alternatively, when determining that the establishment of the connection between the meter device 1 and the appliance 2 has failed, the meter device 1 may resend the second information.

In a second scheme, the appliance management system 10 uses the maintenance terminal 9 to establish the connection between the meter device 1 and the appliance 2.

For example, when receiving the registration data and the identification data, the management device 3 associates this registration data and this identification data with each other, and sends the registration data and the identification data to the maintenance terminal 9 through the fourth communication path 104.

In the second scheme, the management device 3 is configured to, when obtaining the first identifier (registration number) and the second identifier (meter number), send the first information (the first identification and the second identification) to the communication terminal 9.

In the present embodiment, the management device 3 sends a combination of the registration data and the identification data to the upper server 8 connected to the meter device 1 identified by the inputted identification data.

The upper server 8 sends the combination of the registration data and the identification data to the maintenance terminal 9 through the fourth communication path 104.

As described above, the management device 3 sends the combination of the registration data and the identification data that are inputted, to the maintenance terminal 9 through the upper server 8. In other words, the maintenance terminal 9 downloads the registration data and the identification data from the management device 3. Note that, the maintenance terminal 9 may obtain the registration data and the identification data from the management device 3 by way of a memory device such as a memory card (e.g., an SD card). For example, the management device 3 writes the registration data and the identification data in the memory device, and thereafter the maintenance terminal 9 reads out the registration data and the identification data from the memory device. Consequently, the maintenance terminal 9 can obtain the registration data and the identification data without using the fourth communication path 104.

When receiving (downloading) the registration data and the identification data from the management device 3, the maintenance terminal 9 temporarily stores the registration data and the identification data in the memory (not shown) while the registration data and the identification data are associated with each other. After receiving the registration data and the identification data from the management device 3, the communication terminal 9 sends the registration data temporarily stored in the memory to the meter device 1 identified by the identification data associated with this registration data through the third communication path 103.

In short, the communication terminal 9 is configured to, when receiving the first information, send the first information to the meter device 1 identified by the second identifier (meter number) included in the first information.

The maintenance terminal 9 can communicate with the meter device 1 only at a close range. Hence, to send the registration data and the identification data from the maintenance terminal 9 to the meter device 1, the worker carrying the maintenance terminal 9 sends the registration data from the maintenance terminal 9 in a vicinity of the intended meter device 1.

Note that, the maintenance terminal 9 has a function of displaying information such as an address of a facility identified by the identification data temporarily stored in the memory in response to a manual operation of the manual interface unit 92. Therefore, the worker can identify the desired facility 100 by seeing the information displayed by the display unit 91.

When receiving the registration data from the maintenance terminal 9, the meter device 1 sends this registration data to the appliance 2 in the same facility 100 through the first communication path 101. As described above, the meter device 1 is configured to, when receiving the first information from the maintenance terminal 9, send the second information to the appliance 2 in the connectionless protocol. In other words, the meter device 1 is configured to send the second information to the appliance 2 without establishing the connection with the appliance 2.

When receiving the registration data from the meter device 1, the appliance 2 verifies the first data based on the second data. When the first data matches the second data, the appliance 2 establishes the connection with the meter device 1 that is the sender of the registration data, and starts to communicate with this meter device 1.

Accordingly, the appliance 2 is configured to, when receiving the second information, judge whether the first identifier (first data) included in the second information matches the first identifier (second data) allocated to this appliance 2. The appliance 2 is configured to, when the first identifier included in the second information matches the first identifier allocated to this appliance 2, perform the setting process of selecting the meter device 1 identified by the second identifier included in the second information as the communication partner.

Additionally, the meter device 1 judges whether establishment of the connection with the appliance 2 has succeeded, at a time at which a predetermined time has elapsed from sending the registration data to the appliance 2, and sends a result of this judgment to the maintenance terminal 9 through the third communication path 103.

Consequently, for example, if the establishment of the connection between the meter device 1 and the appliance 2 results in failure, the worker can retry to establish the connection between the meter device 1 and the appliance 2 by resending the registration data to the meter device 1 from the maintenance terminal 9.

The worker conducts an operation of sending the registration data at the desired facility 100, and therefore when the establishment of the connection between the meter device 1 and the appliance 2 has failed, the worker can visit the facility 100 to examine and solve problems.

In the second scheme, when determining that the establishment of the connection between the meter device 1 and the appliance 2 has failed, the meter device 1 notifies the maintenance terminal 9 of failure of the establishment of the connection between the meter device 1 and the appliance 2. Alternatively, when determining that the establishment of the connection between the meter device 1 and the appliance 2 has failed, the meter device 1 may resend the second information.

In a third scheme, the appliance management system 10 uses the first scheme of establishing the connection between the meter device 1 and the appliance 2 by use of the second communication path 102 in combination with the second scheme of establishing the connection between the meter device 1 and the appliance 2 by use of the maintenance terminal 9.

Accordingly, when the registration data and the identification data are inputted, the management device 3 sends the registration data to the meter device 1 identified by the identification data through the second communication path 102. Further, when the connection between the meter device 1 and the cooperation device 2 has not yet been established even after a lapse of the predetermined time period from sending the registration data through the second communication path 102, the management device 3 associates the registration data with the identification data and sends the registration data and the identification data to the communication terminal 9 through the fourth communication path 104.

In summary, the management device 3 is configured to, when obtaining the first identifier (registration number) and the second identifier (meter number), send the first information to the meter device 1 identified by the second identifier (meter number) obtained. The management device 3 is configured to, when the connection between the appliance 2 and the meter device 1 respectively identified by the first identifier and the second identifier included in the first information has not yet been established even after a lapse of the predetermined time period from sending the first information, send the first information to the maintenance terminal 9.

In this case, as with the second scheme, when receiving the registration data and the identification data from the management device 3, the maintenance terminal 9 sends the registration data to the meter device 1 identified by the identification data associated with this registration data through the third communication path 103. In short, the maintenance terminal 9 is configured to, when receiving the first information, send the first information to the meter device 1 identified by the second identifier included in the first information.

Moreover, when receiving the registration data from any of the management device 3 and the maintenance terminal 9, the meter device 1 sends this registration data to the appliance 2 in the same facility 100 through the first communication path 101. As described above, the meter device 1 is configured to send the second information to the appliance 2 in the connectionless protocol when receiving the first information irrespective of the sender of the first information. In other words, the meter device 1 is configured to send the second information to the appliance 2 without establishing the connection with the appliance 2.

When receiving the registration data from the meter device 1, the appliance 2 verifies the first data based on the second data. When the first data matches the second data, the appliance 2 establishes the connection with the meter device 1 that is the sender of the registration data, and starts to communicate with this meter device 1.

Accordingly, the appliance 2 is configured to, when receiving the second information, judge whether the first identifier (first data) included in the second information matches the first identifier (second data) allocated to this appliance 2. The appliance 2 is configured to, when the first identifier included in the second information matches the first identifier allocated to this appliance 2, perform the setting process of selecting the meter device 1 identified by the second identifier included in the second information as the communication partner.

According to the third scheme, when the meter device 1 receiving the registration data from the meter device 1 has failed to establish connection with the appliance 2, the establishment of the connection between the meter device 1 and the appliance 2 can be retried by resending the registration data from the communication terminal 9 to the meter device 1.

At the time of retrying, the worker conducts the operation of sending the registration data at the desired facility 100, and therefore when the establishment of the connection between the meter device 1 and the appliance 2 has failed again, the worker can visit the facility 100 to examine and solve problems.

Note that, in any of the first to third schemes, data sent from the management device 3 to the meter device 1 may not be the registration data of the appliance 2 per se, but may be data for enabling associating the meter device 1 and the appliance 2 with each other (relating the meter device 1 and the appliance 2 to each other).

### 2. Operations of Appliance Management System 10

### 2.1 First Scheme

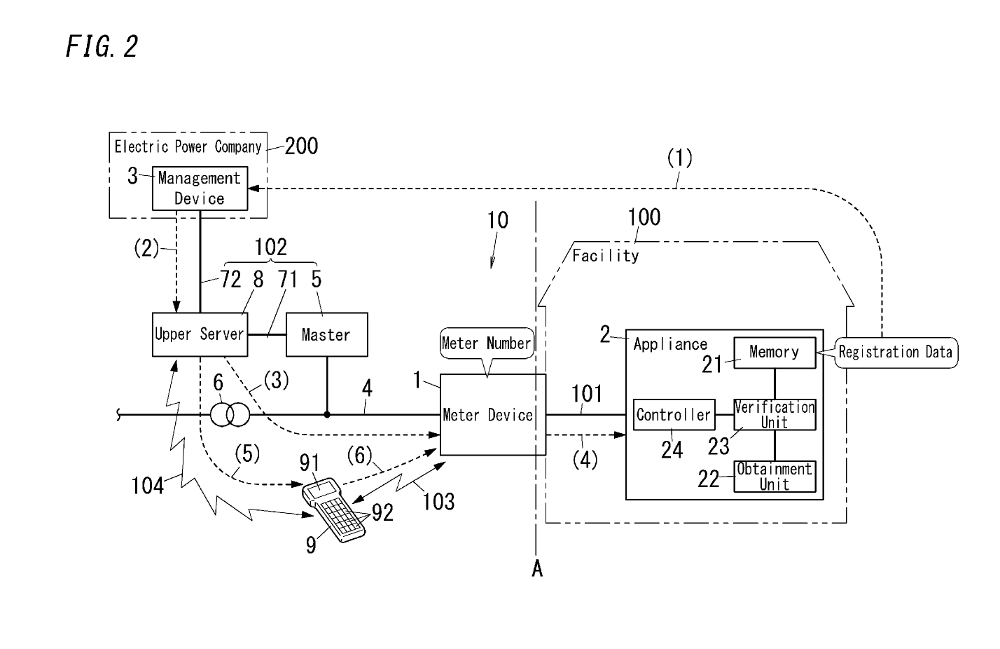

Hereinafter, an appliance management method that is conducted subsequent to addition of a new appliance 2 in the appliance management system 10 for the purpose of establishing the connection between the meter device 1 and the appliance 2 according to the first scheme is described with reference to FIG. 2.

First, a user of the facility in which the appliance 2 is newly added checks the registration data by seeing to nameplate of this appliance 2, for example, and inputs this registration data together with the identification data such as the address of the facility 100 in the management device 3 through the Internet by use of an information terminal (not shown) (see (1) in FIG. 2). Alternatively, the user sends the registration data and the identification data to the electric power company 200 by mail, and a person in charge in the electric power company 200 inputs the registration data and the identification data in the management device 3.

Thereafter, the management device 3 searches for the meter number associated with the inputted information such as the address, and uses this meter number as the identification data to send the inputted registration data to the meter device 1 to which this meter number is allocated, through the second communication path 102 (see (2) and (3) in FIG. 2).

Subsequently, when receiving the registration data from the management device 3, the meter device 1 sends the received registration data to the appliance 2 in the same facility 100 through the first communication path 101 (see (4) in FIG. 2).

When receiving the registration data, the appliance 2 obtains the registration data by the obtainment unit 22, and verifies by the verification unit 23 the obtained registration data (first data) based on the registration data (second data) stored in the memory 21. When the registration data (first data) matches the registration data (second data), the appliance 2 establishes by the controller 24 the communication with the meter device 1 that is the sender of the registration data, and starts to communicate with the meter device 1.

### 2.2 Second Scheme

Hereinafter, the appliance management method that is conducted subsequent to addition of a new appliance 2 in the appliance management system 10 for the purpose of establishing the connection between the meter device 1 and the appliance 2 according to the second scheme is described with reference to FIG. 2.

First, a user of the facility in which the appliance 2 is newly added checks the registration data by seeing to nameplate of this appliance 2, for example, and inputs this registration data together with the identification data such as the address of the facility 100 in the management device 3 through the Internet by use of an information terminal (not shown) (see (1) in FIG. 2). Alternatively, the user sends the registration data and the identification data to the electric power company 200 by mail, and a person in charge in the electric power company 200 inputs the registration data and the identification data in the management device 3.

Thereafter, the management device 3 associates the registration data and the identification data with each other and sends them to the maintenance terminal 9 through the fourth communication path 104 (see (5) in FIG. 2). Consequently, the maintenance terminal 9 stores a combination of the registration data and the identification data in the memory temporarily.

The worker moves to the desired facility 100 (i.e., identified by the stored identification data) with carrying the maintenance terminal 9 that stores the registration data and the identification data, and sends the registration data to the meter device 1 through the third communication path 103 on site (see (6) in FIG. 2). Note that, at this time, the worker identifies the desired facility 100 by seeing information displayed on the display unit 91 of the maintenance terminal 9.

Subsequently, when receiving the registration data from the maintenance terminal 9, the meter device 1 sends the received registration data to the appliance 2 in the same facility 100 through the first communication path 101 (see (4) in FIG. 2).

When receiving the registration data, the appliance 2 obtains the registration data by the obtainment unit 22, and verifies by the verification unit 23 the obtained registration data (first data) based on the registration data (second data) stored in the memory 21. When the registration data (first data) matches the registration data (second data), the appliance 2 establishes by the controller 24 the communication with the meter device 1 that is the sender of the registration data, and starts to communicate with the meter device 1.

### 2.3 Third Scheme

Hereinafter, the appliance management method that is conducted subsequent to addition of a new appliance 2 in the appliance management system 10 for the purpose of establishing the connection between the meter device 1 and the appliance 2 according to the third scheme is described with reference to FIG. 2.

First, a user of the facility in which the appliance 2 is newly added checks the registration data by seeing to nameplate of this appliance 2, for example, and inputs this registration data together with the identification data such as the address of the facility 100 in the management device 3 through the Internet by use of an information terminal (not shown) (see (1) in FIG. 2). Alternatively, the user sends the registration data and the identification data to the electric power company 200 by mail, and a person in charge in the electric power company 200 inputs the registration data and the identification data in the management device 3.

Thereafter, the management device 3 searches for the meter number associated with the inputted information such as the address, and uses this meter number as the identification data to send the inputted registration data to the meter device 1 to which this meter number is allocated, through the second communication path 102 (see (2) and (3) in FIG. 2).

Subsequently, when receiving the registration data from the management device 3, the meter device 1 sends the received registration data to the appliance 2 in the same facility 100 through the first communication path 101 (see (4) in FIG. 2).

When receiving the registration data, the appliance 2 obtains the registration data by the obtainment unit 22, and verifies by the verification unit 23 the obtained registration data (first data) based on the registration data (second data) stored in the memory 21. When the registration data (first data) matches the registration data (second data), the appliance 2 establishes by the controller 24 the communication with the meter device 1 that is the sender of the registration data, and starts to communicate with the meter device 1.

When the establishment of the connection between the meter device 1 and the appliance 2 has failed, the management device 3 associates the registration data and the identification data with each other and sends them to the maintenance terminal 9 through the fourth communication path 104 (see (5) in FIG. 2). Consequently, the maintenance terminal 9 stores a combination of the registration data and the identification data in the memory temporarily.

The worker moves to the desired facility 100 (i.e., identified by the stored identification data) with carrying the maintenance terminal 9 that stores the registration data and the identification data, and sends the registration data to the meter device 1 through the third communication path 103 on site (see (6) in FIG. 2). Note that, at this time, the worker identifies the desired facility 100 by seeing information displayed on the display unit 91 of the maintenance terminal 9.

Subsequently, when receiving the registration data from the maintenance terminal 9, the meter device 1 sends the received registration data to the appliance 2 in the same facility 100 through the first communication path 101 (see (4) in FIG. 2).

When receiving the registration data, the appliance 2 obtains the registration data by the obtainment unit 22, and verifies by the verification unit 23 the obtained registration data (first data) based on the registration data (second data) stored in the memory 21. When the registration data (first data) matches the registration data (second data), the appliance 2 establishes by the controller 24 the communication with the meter device 1 that is the sender of the registration data, and starts to communicate with the meter device 1.

### 3. Features of Appliance Management System 10

As described above, the appliance management system 10 of the present embodiment includes the following first feature. According to the first feature of the appliance management system 10, the appliance management system 10 includes a meter device 1 configured to measure a predetermined physical amount; an appliance 2 having a predetermined function; and a management device 3. The management device 3 is configured to, when obtaining a first identifier allocated to the appliance 2 and a second identifier allocated to the meter device 1, send first information including the first identifier and the second identifier. The meter device 1 is configured to: when receiving the first information, judge whether the second identifier included in the first information matches the second identifier allocated to this meter device 1; and when the second identifier included in the first information matches the second identifier allocated to this meter device 1, send second information including the first identifier included in the first information and the second identifier allocated to this meter device 1. The appliance 2 is configured to: when receiving the second information, judge whether the first identifier included in the second information matches the first identifier allocated to this appliance 2; and when the first identifier included in the second information matches the first identifier allocated to this appliance 2, perform a setting process of selecting the meter device 1 identified by the second identifier included in the second information as a communication partner.

Further, the appliance management system 10 of the present embodiment includes the following second feature in addition to the first feature. According to the second feature of the appliance management system 10, the appliance 2 and the meter device 1 each have a function of communicating in a connection oriented protocol. The appliance 2 is configured to, after completion of the setting process, perform a connection process of sending a connection request for establishing connection with the communication partner in the connection oriented protocol. The meter device 1 is configured to, when receiving the connection request, send a connection reply to a sender of the connection request. The appliance 2 is configured to, when receiving the connection reply after completion of the connection process, determine that connection with the communication partner is established. Note that the second feature of the appliance management system 10 is optional.

Furthermore, the appliance management system 10 of the present embodiment includes the following third feature in addition to the second feature. According to the third feature of the appliance management system 10, the appliance 2 and the meter device 1 each have a function of communicating in a connectionless protocol. The meter device 1 is configured to send the second information in the connectionless protocol. Note that the third feature of the appliance management system 10 is optional.

Accordingly, the appliance management system 10 of the present embodiment described above can establish the connection between the meter device 1 and the appliance 2 by using the network between the management device 3 and the meter device 1 without requiring manual inputting of data for identifying the appliance 2 to the meter device 1.

When the registration data received by the appliance 2 from the management device 3 through the meter device 1 matches the registration data preliminarily allocated to this appliance 2, this appliance 2 can determine that this meter device 1 is installed in the same facility 100 in which the appliance 2 is installed. Hence, this appliance management system 10 can facilitate settings for establishing the connection between the appliance 2 and the meter device 1.

According to the appliance management system 10 of the present embodiment, it is possible to establish the connection between the meter device 1 and the appliance 2 without manually inputting data for identifying the appliance 2 to the meter device 1. Consequently, there is an advantage that the settings for establishing the connection between the appliance 2 and the meter device 1 are facilitated.

The appliance management system 10 of the present embodiment performs the following appliance management method. This appliance management method is an appliance management method for establishing connection between a meter device 1 configured to measure a predetermined physical amount and an appliance 2 having a function of communicating with the meter device 1. The appliance management method includes the following first feature. According to the first feature of the appliance management method, the appliance management method includes the first to sixth steps. The first step is a step of, by a management device 3, obtaining a first identifier allocated to the appliance 2 and a second identifier allocated to the meter device 1. The second step is a step of, by the management device 3, sending first information including the first identifier and the second identifier. The third step is a step of, by the meter device 1, receiving the first information and judging whether the second identifier included in the first information matches the second identifier allocated to this meter device 1. The fourth step is a step of, by the meter device 1, sending second information including the first identifier included in the first information and the second identifier allocated to this meter device 1 when the second identifier included in the first information matches the second identifier allocated to this meter device 1. The fifth step is a step of, by the appliance 2, receiving the second information and judging whether the first identifier included in the second information matches the first identifier allocated to this appliance 2. The sixth step is a step of, by the appliance 2, selecting the meter device 1 identified by the second identifier included in the second information as a communication partner when the first identifier matches the first identifier allocated to this appliance 2.

The appliance management method includes the following second feature in addition to the first feature of the appliance management method. According to the second feature of the appliance management method, the appliance management method further includes seventh to ninth steps. The seventh step is a step of, by the appliance 2, sending a connection request for establishing connection with the communication partner in a connection oriented protocol, after the sixth step. The eighth step is a step of, by the meter device 1, receiving the connection request and sending a connection reply to a sender of the connection request. The ninth step is a step of, by the appliance 2, determining that connection with the communication partner is established when receiving the connection reply. Note that, the second feature of the appliance management method is optional.

The appliance management method includes the following third feature in addition to the second feature of the appliance management method. According to the third feature of the appliance management method, in the fourth step, the meter device 1 sends the second information in a connectionless protocol. Note that, the third feature of the appliance management method is optional.

### 3.1 First Scheme

The appliance management system 10 of the present embodiment employing the first scheme is defined as follows. That is, the appliance management system 10 includes: the meter device 1 installed in the facility 100 and to measure electric energy supplied to this facility 100; the appliance 2 installed in the facility 100 and having the function of communicating with the meter device 1 through the first communication path 101; and the management device 3 to be operated by the electric power company 200 and to communicate with the meter device 1 through the second communication path 102. When the registration data allocated to the appliance 2 and the identification data for identifying the meter device 1 installed in the same facility in which this appliance 2 is installed are inputted into the management device 3, the management device 3 sends the registration data to the meter device 1 identified by the identification data through the second communication path 102. When receiving the registration data from the management device 3, the meter device 1 sends this registration data to the appliance 2 through the first communication path 101. When the registration data received by the appliance 2 from the meter device 1 matches the registration data allocated to this appliance 2, the appliance 2 establishes the connection with this meter device 1.

The appliance management system 10 employing the first scheme can be interpreted as including the following fourth feature in addition to the third feature of the appliance management system 10. According to the fourth feature of the appliance management system 10, the management device 3 is configured to, when obtaining the first identifier and the second identifier, send the first information to the meter device 1 identified by the second identifier obtained. Note that, the fourth feature of the appliance management system is optional.

As described above, the appliance management system 10 using the first scheme can establish the connection between the meter device 1 and the appliance 2 without using the maintenance terminal 9, and therefore give an advantage that the worker need not visit the facility 100.

In other words, the appliance management system 10 of the present embodiment using the first scheme performs the following appliance management method.

This appliance management method is used in the appliance management system 10 including: the meter device 1 installed in the facility 100 and to measure electric energy supplied to this facility 100; the appliance 2 installed in the facility 100 and having the function of communicating with the meter device 1 through the first communication path 101; and the management device 3 to be operated by the electric power company 200 and to communicate with the meter device 1 through the second communication path 102. The appliance management method is for establishing the connection between the appliance 2 and the meter device 1. In the appliance management method, when the registration data allocated to the appliance 2 and the identification data for identifying the meter device 1 installed in the same facility in which this appliance 2 is installed are inputted into the management device 3, the management device 3 sends the registration data to the meter device 1 identified by the identification data through the second communication path 102. When receiving the registration data from the management device 3, the meter device 1 sends this registration data to the appliance 2 through the first communication path 101. When the registration data received by the appliance 2 from the meter device 1 matches the registration data allocated to this appliance 2, the appliance 2 establishes the connection with this meter device 1.

The appliance management method performed by the appliance management system 10 employing the first scheme can be interpreted as including the following fourth feature in addition to the above third feature of the appliance management method. According to the fourth feature of the appliance management method, in the second step, the management device 3 sends the first information to the meter device 1 identified by the second identifier obtained. Note that, the fourth feature of the appliance management method is optional.

### 3.2 Second Scheme

The appliance management system 10 of the present embodiment employing the second scheme is defined as follows. That is, the appliance management system 10 includes: the meter device 1 installed in the facility 100 and to measure electric energy supplied to this facility 100; the appliance 2 installed in the facility 100 and having the function of communicating with the meter device 1 through the first communication path 101; the maintenance terminal 9 to perform near field communication with the meter device 1 through the third communication path 103; and the management device 3 to be operated by the electric power company 200 and to communicate with the maintenance terminal 9 through the fourth communication path 104. When the registration data allocated to the appliance 2 and the identification data for identifying the meter device 1 installed in the same facility in which this appliance 2 is installed are inputted into the management device 3, the management device 3 associates the registration data and the identification data with each other and sends the registration data and the identification data to the maintenance terminal 9 through the fourth communication path 104. When receiving the registration data and the identification data from the management device 3, the maintenance terminal 9 sends the registration data to the meter device 1 identified by the identification data associated with this registration data through the third communication path 103. When receiving the registration data from the maintenance terminal 9, the meter device 1 sends this registration data to the appliance 2 through the first communication path 101. When the registration data received by the appliance 2 from the meter device 1 matches the registration data allocated to this appliance 2, the appliance 2 establishes the connection with this meter device 1.

The appliance management system 10 employing the second scheme can be interpreted as including the following fifth feature in addition to the third feature of the appliance management system 10. According to the fifth feature of the appliance management system 10, According to the fifth feature of the appliance management system 10, the appliance management system 10 further includes the communication terminal (maintenance terminal) 9 configured to communicate with the management device 3 and the meter device 1. The management device 3 is configured to, when obtaining the first identifier and the second identifier, send the first information to the maintenance terminal 9. The maintenance terminal 9 is configured to, when receiving the first information, send the first information to the meter device 1 identified by the second identifier included in the first information. Note that, the fifth feature of the appliance management system 10 is optional.

As described above, even if the first communication path (A-route) 101 is not formed between the management device 3 and the meter device 1, the appliance management system 10 using the second scheme can establish the connection between the meter device 1 and the appliance 2 in the facility 100 by use of the maintenance terminal 9. Additionally, according to the second scheme, the worker carrying the maintenance terminal 9 conducts an operation of sending the registration data at the desired facility 100, and therefore when the establishment of the connection between the meter device 1 and the appliance 2 has failed, the worker can examine and solve problems on site.

In other words, the appliance management system 10 of the present embodiment using the second scheme performs the following appliance management method.

This appliance management method is used in the appliance management system 10 including: the meter device 1 installed in the facility 100 and to measure electric energy supplied to this facility 100; the appliance 2 installed in the facility 100 and having the function of communicating with the meter device 1 through the first communication path 101; the maintenance terminal 9 to perform near field communication with the meter device 1 through the third communication path 103; and the management device 3 to be operated by the electric power company 200 and to communicate with the maintenance terminal 9 through the fourth communication path 104. This appliance management method is for establishing the connection between the appliance 2 and the meter device 1. In the appliance management method, when the registration data allocated to the appliance 2 and the identification data for identifying the meter device 1 installed in the same facility in which this appliance 2 is installed are inputted into the management device 3, the management device 3 associates the registration data and the identification data with each other and sends the registration data and the identification data to the maintenance terminal 9 through the fourth communication path 104. When receiving the registration data and the identification data from the management device 3, the maintenance terminal 9 sends the registration data to the meter device 1 identified by the identification data associated with this registration data through the third communication path 103. When receiving the registration data from the maintenance terminal 9, the meter device 1 sends this registration data to the appliance 2 through the first communication path 101. When the registration data received by the appliance 2 from the meter device 1 matches the registration data allocated to this appliance 2, the appliance 2 establishes the connection with this meter device 1.

The appliance management method performed by the appliance management system 10 employing the second scheme can be interpreted as including the following fifth feature in addition to the above third feature of the appliance management method. According to the fifth feature of the appliance management method, in the second step, when obtaining the first identifier and the second identifier, the management device 3 sends the first information to the communication terminal (maintenance terminal) 9; and when receiving the first information, the maintenance terminal 9 sends the first information to the meter device 1 identified by the second identifier included in the first information. Note that, the fifth feature of the appliance management method is optional.

### 3.3 Third Scheme

The appliance management system 10 of the present embodiment employing the third scheme is defined as follows. That is, the appliance management system 10 includes: the meter device 1 installed in the facility 100 and to measure electric energy supplied to this facility 100; the appliance 2 installed in the facility 100 and having the function of communicating with the meter device 1 through the first communication path 101; the management device 3 to be operated by the electric power company 200 and to communicate with the meter device 1 through the second communication path 102; and the maintenance terminal 9 to perform near field communication with the meter device 1 through the third communication path 103 and to communicate with the management device 3 through the fourth communication path 104. When the registration data allocated to the appliance 2 and the identification data for identifying the meter device 1 installed in the same facility in which this appliance 2 is installed are inputted into the management device 3, the management device 3 sends the registration data to the meter device 1 identified by the identification data through the second communication path 102. When the connection between the meter device 1 and the appliance 2 has not yet been established even after a lapse of the predetermined time period from sending the registration data, the management device 3 associates the registration data and the identification data with each other and sends the registration data and the identification data to the maintenance terminal 9 through the fourth communication path 104. When receiving the registration data and the identification data from the management device 3, the maintenance terminal 9 sends the registration data to the meter device 1 identified by the identification data associated with this registration data through the third communication path 103. When receiving the registration data from any of the management device 3 and maintenance terminal 9, the meter device 1 sends this registration data to the appliance through the first communication path 101. When the registration data received by the appliance 2 from the meter device 1 matches the registration data allocated to this appliance 2, the appliance 2 establishes the connection with this meter device 1.

The appliance management system 10 employing the third scheme can be interpreted as including the following sixth feature in addition to the fourth feature of the appliance management system 10. According to the sixth feature of the appliance management system 10, the appliance management system 10 further includes the communication terminal (maintenance terminal) 9 configured to communicate with the management device 3 and the meter device 1. The management device 3 is configured to, when connection between the appliance 2 and the meter device 1 respectively identified by the first identifier and the second identifier included in the first information has not yet been established even after a lapse of the predetermined time period from sending the first information, send the first information to the maintenance terminal 9. The maintenance terminal 9 is configured to, when receiving the first information, send the first information to the meter device 1 identified by the second identifier included in the first information. Note that, the sixth feature of the appliance management system 10 is optional.

Note that, the appliance management system 10 employing the third scheme may include the following seventh feature in addition to the sixth feature of the appliance management system 10. According to the seventh feature of the appliance management system 10, the meter device 1 is configured to send the connection establishment signal to the management device 3 after sending the connection response. The management device 3 is configured to, when having not yet received the connection establishment signal even after a lapse of the predetermined time period from sending the first information, send the first information to the maintenance terminal 9.

As described above, according to the appliance management system 10 using the third scheme, if the establishment of the connection between the meter device 1 and the appliance 2 has succeeded on the first try, the worker need not visit the facility 100. If the establishment of the connection between the meter device 1 and the appliance 2 has failed, the worker can examine and solve problems on site at the time of retrying the establishment of the connection.

In other words, the appliance management system 10 of the present embodiment using the third scheme performs the following appliance management method.

This appliance management method is used in the appliance management system 10 including: the meter device 1 installed in the facility 100 and to measure electric energy supplied to this facility 100; the appliance 2 installed in the facility 100 and having the function of communicating with the meter device 1 through the first communication path 101; the management device 3 to be operated by the electric power company 200 and to communicate with the meter device 1 through the second communication path 102; and the maintenance terminal 9 to perform near field communication with the meter device 1 through the third communication path 103 and to communicate with the management device 3 through the fourth communication path 104. The appliance management method is for establishing the connection between the appliance 2 and the meter device 1. In the appliance management method, when the registration data allocated to the appliance 2 and the identification data for identifying the meter device 1 installed in the same facility in which this appliance 2 is installed are inputted into the management device 3, the management device 3 sends the registration data to the meter device 1 identified by the identification data through the second communication path 102. When the connection between the meter device 1 and the appliance 2 has not yet been established even after a lapse of the predetermined time period from sending the registration data, the management device 3 associates the registration data and the identification data with each other and sends the registration data and the identification data to the maintenance terminal 9 through the fourth communication path 104. When receiving the registration data and the identification data from the management device 3, the maintenance terminal 9 sends the registration data to the meter device 1 identified by the identification data associated with this registration data through the third communication path 103. When receiving the registration data from any of the management device 3 and maintenance terminal 9, the meter device 1 sends this registration data to the appliance through the first communication path 101. When the registration data received by the appliance 2 from the meter device 1 matches the registration data allocated to this appliance 2, the appliance 2 establishes the connection with this meter device 1.

The appliance management method performed by the appliance management system 10 employing the third scheme can be interpreted as including the following sixth feature in addition to the above fourth feature of the appliance management method. According to the sixth feature of the appliance management method, the appliance management method further includes the tenth step and the eleventh step. In the tenth step, when connection between the appliance 2 and the meter device 1 respectively identified by the first identifier and the second identifier included in the first information has not yet been established even after a lapse of a predetermined time period from sending the first information, the management device 3 sends the first information to the maintenance terminal 9 configured to communicate with the management device 3 and the meter device 1. In the eleventh step, when receiving the first information, the maintenance terminal 9 sends the first information to the meter device 1 identified by the second identifier included in the first information. Note that, the sixth feature of the appliance management method is optional.

Note that, the appliance management method performed by the appliance management system 10 employing the third scheme may include the following seventh feature in addition to the above sixth feature of the appliance management method. According to the seventh feature of the appliance management method, the appliance management method further includes the twelfth step and the thirteenth step. In the twelfth step, the meter device 1 sends the connection establishment signal to the management device 3 after sending the first information. In the thirteenth step, when having not yet received the connection establishment signal even after a lapse of the predetermined time period from sending the first information, the management device 3 sends the first information to the maintenance terminal 9.

### 4. Supplement

Note that, the communication between the communication terminal 9 and the meter device 1 is not limited to the near field communication through the third communication path 103, but may be long distance communication or wired communication using dedicated cables as with the communication between the upper server 8 and the communication terminal 9 through the fourth communication path 104. In this case, the worker can operates the maintenance terminal 9 to allow the maintenance terminal 9 to communicate with the meter device 1, also at a remote location from the facility 100.

Hereinafter, how to ensure the security of communication between the meter device 1 and the appliance 2 in the appliance management system 10 of the present embodiment is briefly described.

For an example, the meter device 1 stores the registration data received from the management device 3 or the maintenance terminal 9 in its memory, and thereafter sends the registration data to the appliance 2, thereby distributing the same registration data to the meter device 1 and the appliance 2. In this case, the meter device 1 and the appliance 2 each use the registration data as a common key for communication, and therefore the security of communication can be ensured.

Further, the management device 3 may encrypt the common key used for communication in the first encryption manner allowing decryption by the meter device 1 only, and encrypt the common key use for communication in the second encryption manner allowing decryption by the appliance 2 only, and send the encrypted common keys together with the registration data to the meter device 1.

In this case, the meter device 1 obtains the common key by decrypting by itself the common key encrypted in the first encryption manner, and sends the common key encrypted in the second encryption manner to the appliance 2 together with the registration data.

Consequently, the appliance 2 can obtain the common key by decrypting the common key encrypted in the second encryption manner. The common key is distributed to the meter device 1 and the appliance 2 in the aforementioned manner, and therefore the security of communication can be ensured.

### Second Embodiment

### 1. Configuration of Appliance Management System 10

The appliance management system 10 of the present embodiment is different from the appliance management system 10 of the first embodiment in that the appliance management system 10 of the present embodiment establishes the connection between the meter device 1 and the appliance 2 without using the network between the management device 3 and the meter device 1. Hereinafter, components common to the present embodiment and the first embodiment are designated by the same reference signs, and explanations thereof are omitted.

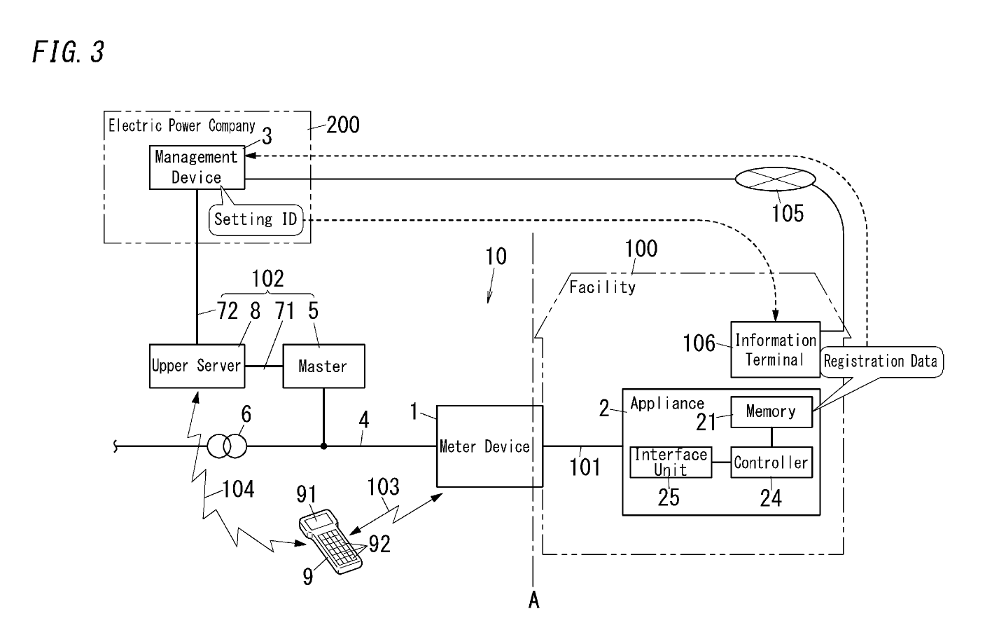

As shown in FIG. 3, there is an information terminal 106 installed in the facility 100. For example, the information terminal 106 is a personal computer that can communicate with the management device 3 through the Internet 105. Hence, a user (a resident of the facility 100) can input the registration data and the identification data in the management device 3 while accessing the website provided by the management device 3 of the electric power company 200 through the Internet 105 by use of the information terminal 106.

When the registration data and the identification data are inputted in the management device 3, based on the registration data and the identification data the management device 3 issues a setting ID necessary for communication between the appliance 2 associated with this registration data and the meter device 1 associated with this identification data.

In summary, the management device 3 is configured to, when obtaining the first identifier allocated to the appliance 2 and the second identifier allocated to the meter device 1, produce the setting code (setting ID) for identifying the meter device 1 associated with the second identifier based on the first identifier and the second identifier.

In this regard, the setting ID is not the registration data per se or the identification data per se. The setting ID is data processed based on at least one of the registration data and the identification data. Hence, the setting ID necessary for communication between the meter device 1 and the appliance 2 is different at least for each of the meter devices 1. To communicate with a certain meter device 1, the appliance 2 requires the setting ID issued based on this meter device 1. Note that, the setting ID may be different not only for each of the meter devices 1 but also each of the appliances 2.

The management device 3 provides the issued setting ID to the facility 100 identified by the inputted identification data. In the example shown in FIG. 3, while the user accesses the website provided by the management device 3 of the electric power company 200 through the Internet 105 by use of the information terminal 106, the setting ID is sent to the information terminal 106 from the management device 3. The management device 3 provides the setting ID to the facility 100 by sending the setting ID to the information terminal 106 via the Internet 105.

In this regard, the appliance 2 includes an interface unit 25 for inputting the setting ID instead of the obtainment unit 22 and the verification unit 23. For example, when the user obtains the setting ID issued by the management device 3 at the information terminal 106, the user can input the setting ID by use of the interface unit 25 of the appliance 2. Note that, when the appliance 2 and the information terminal 106 are connected to be capable of communicating with each other, the information terminal 106 may be configured to transfer the obtained setting ID to the appliance 2 through the interface unit 25.

The appliance 2 is configured to, when receiving the setting code (setting ID), perform the setting process of selecting the meter device 1 identified by the setting code as the communication partner. Further, the appliance 2 is configured to, after completion of the setting process, perform the connection process of sending the connection request for establishing connection with the communication partner in the connection oriented protocol. The appliance 2 is configured to, when receiving the connection reply after completion of the connection process, determine that connection with the communication partner is established.

As described, when the setting ID issued by the management device 3 is inputted to the appliance 2 through the interface unit 25, the appliance 2 uses this setting ID to establish the connection with the meter device 1 by the controller 24, and starts to communicate with the meter device 1. In summary, when the appliance 2 newly provided receives the setting ID issued based on the registration data of this appliance 2 and the identification data, this appliance 2 accepts the meter device 1 identified by this ID as the communication partner. In other words, after completion of the connection with the meter device 1 in the same facility, the appliance 2 can operate in cooperation with this meter device 1 by communicating with this meter device 1.

### 2. Operations of Appliance Management System 10

Hereinafter, an appliance management method that is conducted subsequent to addition of a new appliance 2 in the appliance management system 10 for the purpose of establishing the connection between the meter device 1 and the appliance 2 is described.

First, the user (resident of the facility 100) accesses the website provided by the management device 3 of the electric power company 200 through the Internet 105 by use of the information terminal 106 and inputs the registration data and the identification data to the management device 3.

When the registration data and the identification data are inputted, the management device 3 issues, based on this registration data and this identification data, the setting ID necessary for communication between the appliance 2 to which this registration data is allocated and the meter device 1 to which this identification data is allocated.

The management device 3 provides the issued setting ID to the facility 100 identified by the inputted identification data. In the example shown in FIG. 3, the management device 3 provides the setting ID to the facility 100 by sending the setting ID to the information terminal 106 via the Internet 105.

When the user obtains the setting ID issued by the management device 3 at the information terminal 106, the user inputs the setting ID by use of the interface unit 25 of the appliance 2.

When the setting ID issued by the management device 3 is inputted through the interface unit 25, the appliance 2 uses this setting ID to establish connection with the meter device 1 by the controller 24, and starts to communicate with the meter device 1.

### 3. Features of Appliance Management System 10

As described above, the appliance management system 10 of the present embodiment includes: the meter device 1 installed in the facility 100 and to measure electric energy supplied to this facility 100; the appliance 2 installed in the facility 100 and having the function of communicating with the meter device 1 through the first communication path 101; and the management device 3 to be operated by the electric power company 200. When the registration data allocated to the appliance 2 and the identification data for identifying the meter device 1 installed in the same facility in which this appliance 2 is installed are inputted, the management device 3 issues, based on the registration data and the identification data, the setting ID necessary for communication between the appliance 2 and the meter device 1. When the setting ID issued by the management device 3 is inputted, the appliance 2 uses this setting ID to establish connection with the meter device 1.

In other words, the appliance management system 10 of the present embodiment includes the following eighth feature. According to the eighth feature of the appliance management system 10, the appliance management system 10 includes: a meter device 1 configured to measure a predetermined physical amount; an appliance 2 having a predetermined function; and a management device 3. The management device 3 is configured to, when obtaining a first identifier allocated to the appliance 2 and a second identifier allocated to the meter device 1, produce a setting code identifying the meter device 1 associated with the second identifier based on the first identifier and the second identifier. The appliance 2 is configured to, when receiving the setting code, perform a setting process of selecting the meter device 1 identified by the setting code as a communication partner.

Further, the appliance management system 10 of the present embodiment includes the following ninth feature in addition to the eighth feature of the appliance management system 10. According to the eighth feature of the appliance management system 10, the appliance 2 and the meter device 1 each have a function of communicating in a connection oriented protocol. The appliance 2 is configured to, after completion of the setting process, perform a connection process of sending a connection request for establishing connection with the communication partner in the connection oriented protocol. The meter device 1 is configured to, when receiving the connection request, send a connection reply to a sender of the connection request. The appliance 2 is configured to, when receiving the connection reply after completion of the connection process, determine that connection with the communication partner is established. Note that, the ninth feature of the appliance management system 10 is optional.

According to the appliance management system 10 of the present embodiment described above, even when the network between the management device 3 and the meter device 1 is not used, the connection between the meter device 1 and the appliance 2 can be established and nevertheless there is no need to manually input data for identifying the appliance 2 to the meter device 1. In summary, when the setting ID issued by the management device 3 is inputted to the appliance 2, the appliance 2 can acknowledge that the meter device 1 identified by this setting ID is installed in the same facility 100 in which this appliance 2 is installed. Hence, this appliance management system 10 can facilitate the setting for establishing the connection between the appliance 2 and the meter device 1.

### 4. Supplement

Note that, transmission of the registration data and the identification data as well as the setting ID between the facility 100 and the electric power company 200 may conducted by mail instead of using the information terminal 106. In this case, the registration data and the identification data are provided from the facility 100 to the electric power company 200 by mail, and are inputted to the management device 3 by a person in charge in the electric power company 200. The setting ID issued by the management device 3 is provided from the electric power company 200 to the facility 100 by mail, and is inputted to the appliance 2 by the user in the facility 100. Note that, the registration data and the identification data are inputted to the management device 3 by use of the information terminal 106 but only the notification of the setting ID may be conducted by mail.

Hereinafter, how to ensure the security of communication between the meter device 1 and the appliance 2 in the appliance management system 10 of the present embodiment is briefly described.

For an example, the management device 3 encrypts the common key used for communication in the first encryption manner allowing decryption by the appliance 2 only, and encrypts the common key use for communication in the second encryption manner allowing decryption by the meter device 1 only, and issues the encrypted common keys together with the setting data. In this case, the appliance 2 obtains the common key by decrypting by itself the common key encrypted in the first encryption manner, and additionally sends the common key encrypted in the second encryption manner to the meter device 1. Consequently, the meter device 1 can obtain the common key by decrypting the common key encrypted in the second encryption manner. The common key is distributed to the meter device 1 and the appliance 2 in the aforementioned manner, and therefore the security of communication can be ensured.

The other configurations and functions are same as those of the first embodiment.

1. An appliance management system, comprising:
a meter device configured to measure a predetermined physical amount;
an appliance having a predetermined function; and
a management device,
the management device being configured to, when obtaining a first identifier allocated to the appliance and a second identifier allocated to the meter device, send first information including the first identifier and the second identifier,
the meter device being configured to
when receiving the first information, judge whether the second identifier included in the first information matches the second identifier allocated to this meter device, and
when the second identifier included in the first information matches the second identifier allocated to this meter device, send second information including the first identifier included in the first information and the second identifier allocated to this meter device, and
the appliance being configured to
when receiving the second information, judge whether the first identifier included in the second information matches the first identifier allocated to this appliance, and
when the first identifier included in the second information matches the first identifier allocated to this appliance, perform a setting process of selecting the meter device identified by the second identifier included in the second information as a communication partner.

2. The appliance management system according to claim 1, wherein:
the appliance and the meter device each have a function of communicating in a connection oriented protocol;
the appliance is configured to, after completion of the setting process, perform a connection process of sending a connection request for establishing connection with the communication partner in the connection oriented protocol;
the meter device is configured to, when receiving the connection request, send a connection reply to a sender of the connection request; and
the appliance is configured to, when receiving the connection reply after completion of the connection process, determine that connection with the communication partner is established.

3. The appliance management system according to claim 2, wherein:
the appliance and the meter device each have a function of communicating in a connectionless protocol; and
the meter device is configured to send the second information in the connectionless protocol.

4. The appliance management system according to claim 3, wherein
the management device is configured to, when obtaining the first identifier and the second identifier, send the first information to the meter device identified by the second identifier obtained.

5. The appliance management system according to claim 4, wherein:
the appliance management system further comprises a communication terminal configured to communicate with the management device and the meter device;
the management device is configured to, when connection between the appliance and the meter device respectively identified by the first identifier and the second identifier included in the first information has not yet been established even after a lapse of a predetermined time period from sending the first information, send the first information to the communication terminal; and
the communication terminal is configured to, when receiving the first information, send the first information to the meter device identified by the second identifier included in the first information.

6. The appliance management system according to claim 5, wherein:
the meter device is configured to send a connection establishment signal to the management device after sending the connection response; and
the management device is configured to, when having not yet received the connection establishment signal even after a lapse of the predetermined time period from sending the first information, send the first information to the communication terminal.

7. The appliance management system according to claim 3, wherein:
the appliance management system further comprises a communication terminal configured to communicate with the management device and the meter device;
the management device is configured to, when obtaining the first identifier and the second identifier, send the first information to the communication terminal; and
the communication terminal is configured to, when receiving the first information, send the first information to the meter device identified by the second identifier included in the first information.

8. An appliance management system, comprising:
a meter device configured to measure a predetermined physical amount;
an appliance having a predetermined function; and
a management device,
the management device being configured to, when obtaining a first identifier allocated to the appliance and a second identifier allocated to the meter device, produce a setting code for identifying the meter device associated with the second identifier based on the first identifier and the second identifier, and
the appliance being configured to, when receiving the setting code, perform a setting process of selecting the meter device identified by the setting code as a communication partner.

9. The appliance management system according to claim 8, wherein:
the appliance and the meter device each have a function of communicating in a connection oriented protocol;
the appliance is configured to, after completion of the setting process, perform a connection process of sending a connection request for establishing connection with the communication partner in the connection oriented protocol;
the meter device is configured to, when receiving the connection request, send a connection reply to a sender of the connection request; and
the appliance is configured to, when receiving the connection reply after completion of the connection process, determine that connection with the communication partner is established.

10. An appliance management method for establishing connection between a meter device configured to measure a predetermined physical amount and an appliance having a function of communicating with the meter device, the method comprising:
a first step of, by a management device, obtaining a first identifier allocated to the appliance and a second identifier allocated to the meter device;
a second step of, by the management device, sending first information including the first identifier and the second identifier;
a third step of, by the meter device, receiving the first information and judging whether the second identifier included in the first information matches the second identifier allocated to this meter device;
a fourth step of, by the meter device, sending second information including the first identifier included in the first information and the second identifier allocated to this meter device when the second identifier included in the first information matches the second identifier allocated to this meter device;
a fifth step of, by the appliance, receiving the second information and judging whether the first identifier included in the second information matches the first identifier allocated to this appliance; and
a sixth step of, by the appliance, selecting the meter device identified by the second identifier included in the second information as a communication partner when the first identifier included in the second information matches the first identifier allocated to this appliance.

11. The appliance management method according to claim 10, wherein
the appliance management method further comprises:
a seventh step of, by the appliance, sending a connection request for establishing connection with the communication partner in a connection oriented protocol, after the sixth step;
an eighth step of, by the meter device, receiving the connection request and sending a connection reply to a sender of the connection request; and
a ninth step of, by the appliance, determining that connection with the communication partner is established when receiving the connection reply.

12. The appliance management method according to claim 11, wherein
in the fourth step, the meter device sends the second information in a connectionless protocol.

13. The appliance management method according to claim 12, wherein
in the second step, the management device sends the first information to the meter device identified by the second identifier obtained.

14. The appliance management method according to claim 13, wherein:
the appliance management method further comprises a tenth step and an eleventh step;
in the tenth step, when connection between the appliance and the meter device respectively identified by the first identifier and the second identifier included in the first information has not yet been established even after a lapse of a predetermined time period from sending the first information, the management device sends the first information to a communication terminal configured to communicate with the management device and the meter device; and
in the eleventh step, when receiving the first information, the communication terminal sends the first information to the meter device identified by the second identifier included in the first information.

15. The appliance management method according to claim 14, wherein:
the appliance management method further comprises a twelfth step and a thirteenth step;
in the twelfth step, the meter device sends a connection establishment signal to the management device after sending the first information; and
in the thirteenth step, when having not yet received the connection establishment signal even after a lapse of the predetermined time period from sending the first information, the management device sends the first information to the communication terminal.
